(19) United States
(12) Patent Application Publication
(10) Pub. No.: US 2024/0052517 A1
(43) Pub. Date: Feb. 15, 2024

(54) NANOPARTICLE FILM, MANUFACTURING METHOD THEREOF, AND DISPLAY PANEL

(71) Applicant: Shenzhen China Star Optoelectronics Semiconductor Display Technology Co., Ltd., Shenzhen, Guangdong (CN)

(72) Inventors: Jinyang ZHAO, Shenzhen, Guangdong (CN); Lixuan CHEN, Shenzhen, Guangdong (CN); Zhiqing SHI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/621,302

(22) PCT Filed: Dec. 17, 2021
(86) PCT No.: PCT/CN2021/139294

§ 371 Date: Dec. 21, 2021

(30) Foreign Application Priority Data
Dec. 10, 2021 (CN) 202111505322.8

(51) Int. Cl. C25D 13/02; C25D 3/02; B82Y 30/00; C09K 11/02; C09K 11/88

(52) U.S. Cl. CPC C25D 13/02; C25D 3/02; B82Y 30/00; C09K 11/02; C09K 11/883

(57) ABSTRACT

A nanoparticle film, a manufacturing method thereof, and a display panel are disclosed. The manufacturing method of the nanoparticle film includes following steps: providing a nanoparticle solution, wherein the nanoparticle solution includes a solvent and a plurality of nanoparticles distributed in the solvent, and a surface of the nanoparticle is provided with a surfactant ligand; and forming the nanoparticle film from the nanoparticle solution by electrodeposition.

### FIELD

The present disclosure relates to a field of nanomaterial technologies, and more particularly, to a nanoparticle film, a manufacturing method thereof, and a display panel.

### BACKGROUND

Nanomaterials are materials having a structural unit with a size ranging from 1 nm to 100 nm. Such size is similar to a coherence length of electrons, Properties of the nanomaterials are significantly changed due to self-organization caused by strong coherence. Moreover, because a nanometer scale is close to a wavelength of light, a volume effect, a surface effect, a quantum size effect, and a macroscopic quantum tunneling effect occur in the nanometer scale, resulting in unique properties of melting point, magnetism, optics, heat conduction, and conductivity. Therefore, the nanometer scale has an important application value in many fields.

Quantum dots are a typical nanomaterial having advantages such as small scale and high power conversion efficiency, and have a vital application prospect in many fields such as illumination, display technology, solar cell, photoswitch, sensor, and detector. In addition, quantum dots have properties such as high brightness, narrow-band emission, adjustable color of emitted light, and good stability, which are suitable for development trends of display fields toward extremely thin body, high brightness, wide color gamut, and high color saturation. Thus, the quantum dots have become the most promising material of display technologies in recent years.

Patterning techniques of quantum-dot nanomaterials are vital when the quantum-dot nanomaterials are applied to many fields such as organic light-emitting diode (LED), display technology, solar cell, photoswitch, sensor, and detector. Currently, patterning techniques of quantum dots mainly include ink-jet printing and photolithography. In photolithography processes, stability of nanoparticles is affected when the nanoparticles are heated at high temperatures, cured by ultraviolet (UV) light, or washed by developers. In printing processes, requirements for printing inks are overly high. Currently, there is no mature and stable mass production material system. In addition, nanoparticles formed by ink-jet printing have poor repeatability and require long a manufacturing time, significantly limiting developments and applications of quantum dots. Recently, a novel patterning technique of quantum-dot nanomaterials can form a quantum-dot patterning thin film by electrodeposition. However, conventional quantum dots have a low quantity of electric charge, leading to a high voltage required by electrodeposition, which limits applications of quantum dots.

### SUMMARY

To solve the above issues, the present disclosure provides a nanoparticle film and a manufacturing method thereof to increase a quantity of electric charge of quantum particles, thereby reducing a required voltage for depositing a nanoparticle film.

The present disclosure provides a method of manufacturing a nanoparticle film, comprising following steps:
providing a nanoparticle solution, wherein the nanoparticle solution comprises a solvent and a plurality of nanoparticles distributed in the solvent, and a surface of the nanoparticles is provided with a surfactant ligand; and
forming the nanoparticle film from the nanoparticle solution by electrodeposition.

In one embodiment, the solvent is a non-polar solvent, and a concentration of the surfactant ligand is greater than a concentration of a critical micelle concentration.

In one embodiment, a mass ratio of the surfactant ligand to the nanoparticles ranges from 1% to 50%.

In one embodiment, the step of forming the nanoparticle film from the nanoparticle solution by electrodeposition comprises following steps:
providing an electrode, and putting the electrode into the nanoparticle solution; and
applying a driving voltage to the electrode to make the nanoparticle solution be deposited on the electrode to form the nanoparticle film, wherein the driving voltage ranges from 50V to 150V.

In one embodiment, the solvent is a polar solvent, and a mass ratio of the surfactant ligand to the nanoparticles ranges from 1% to 50%.

In one embodiment, the mass ratio of the surfactant ligand to the nanoparticles ranges from 1% to 5%.

In one embodiment, the step of forming the nanoparticle film from the nanoparticle solution by electrodeposition comprises following steps:
providing an electrode, and putting the electrode into the nanoparticle solution; and
applying a driving voltage to the electrode to make the nanoparticle solution be deposited on the electrode to form the nanoparticle film, wherein the driving voltage ranges from 1V to 10V.

In one embodiment, the step of providing the nanoparticle solution comprises following steps:
providing a plurality of initial nanoparticles, wherein a surface of the initial nanoparticles is provided with an initial ligand;
mixing the initial nanoparticles with a surfactant to obtain the nanoparticles having the surfactant ligand on the surface of the nanoparticles, wherein a ligand exchange reaction occurs between the initial nanoparticles and the surfactant; and
dissolving the nanoparticles having the surfactant ligand on the surface of the nanoparticles into the solvent to form the nanoparticle solution.

In one embodiment, the step of providing the nanoparticle solution comprises a following step:
dissolving a plurality of initial nanoparticles and the surfactant into the solvent to obtain the nanoparticles having the surfactant ligand on the surface of the nanoparticles and form the nanoparticle solution.

In one embodiment, the nanoparticles are a plurality of quantum dots.

In one embodiment, the surfactant ligand is selected from at least one of an organic sulfonate surfactant ligand, a metal soap sulfonate surfactant ligand, an organic amine surfactant ligand, an N-vinylpyrrolidone polymer, an organic phosphate surfactant ligand, or a phosphate ester surfactant ligand.

The present disclosure further provides a nanoparticle film, comprising a plurality of nanoparticles, wherein a surface of the nanoparticles is provided with a surfactant ligand.

In one embodiment, a mass ratio of the surfactant ligand to the nanoparticles ranges from 1% to 50%.

In one embodiment, a mass ratio of the surfactant ligand to the nanoparticles ranges from 1% to 5%.

In one embodiment, the nanoparticles are a plurality of quantum dots.

In one embodiment, the surfactant ligand is selected from at least one of an organic sulfonate surfactant ligand, a metal soap sulfonate surfactant ligand, an organic amine surfactant ligand, an N-vinylpyrrolidone polymer, an organic phosphate surfactant ligand, or a phosphate ester surfactant ligand.

The present disclosure further provides a display panel, comprising the nanoparticle film of claim 12, wherein the nanoparticles are a plurality of quantum dots.

In one embodiment, a mass ratio of the surfactant ligand to the nanoparticles ranges from 1% to 50%.

In one embodiment, a mass ratio of the surfactant ligand to the nanoparticles ranges from 1% to 5%.

In one embodiment, the nanoparticles are a plurality of quantum dots.

Regarding the beneficial effects:

In the present disclosure, a surface of nanoparticles is modified by a surfactant ligand which can be ionized in a solvent. Therefore, a quantity of electric charge of the nanoparticles is increased, and a driving voltage required by electrodepositing a nanoparticle film is reduced.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a flowchart showing a method of manufacturing a nanoparticle film provided by the present disclosure.

FIG. 2 is a flowchart showing a method of manufacturing a nanoparticle film provided by a first embodiment of the present disclosure.

FIG. 3 is a flowchart showing a method of manufacturing a nanoparticle film provided by a second embodiment of the present disclosure.

FIG. 4 is a schematic view showing an electrode when a voltage is not applied during manufacturing processes of a nanoparticle film provided by the present disclosure.

FIG. 5 is a schematic view showing an electrode when a voltage is applied during manufacturing processes of a nanoparticle film provided by the present disclosure.

FIG. 6 is a structural schematic view showing a display panel provided by the first embodiment of the present disclosure.

FIG. 7 is a structural schematic view showing a display panel provided by the second embodiment of the present disclosure.

FIG. 8 is a structural schematic view showing a display panel provided by a third embodiment of the present disclosure.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature. In addition, terms such as “first” and “second” are used herein for purposes of description and are not intended to indicate or imply relative importance or significance. Thus, features limited by “first” and “second” are intended to indicate or imply including one or more than one these features.

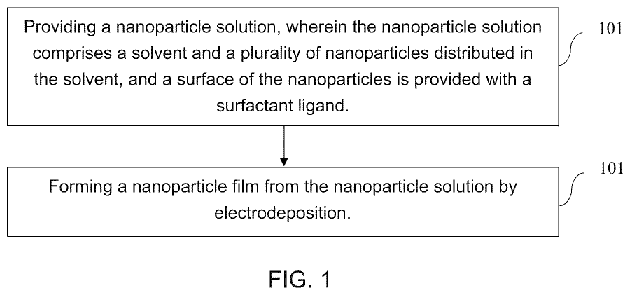

An embodiment of the present disclosure provides a method of manufacturing a nanoparticle film. As shown in FIG. 1, the method of manufacturing the nanoparticle film includes following steps:

Step 101: providing a nanoparticle solution, wherein the nanoparticle solution comprises a solvent and a plurality of nanoparticles distributed in the solvent, and a surface of the nanoparticles is provided with a surfactant ligand.

In the step 101, the solvent may be a polar solvent or a non-polar solvent. To better volatilize the solvent to form a film, the solvent may be an organic solvent or an inorganic solvent having a low boiling point and high volatility.

The nanoparticles for manufacturing the nanoparticle film may be non-metallic inorganic nanoparticles, metal nanoparticles, colloidal nanosheets, or colloidal nanorods. Optionally, the nanoparticles may be quantum dots. A material of the quantum dots of the present disclosure may be core-shell quantum dots. A luminescent core of the core-shell quantum dots may be one of ZnCdSe₂, InP, Cd₂Sse, CdSe, Cd₂SeTe, or InAs. An inorganic protective shell may be at least one of CdS, ZnSe, ZnCdS₂, ZnS, or ZnO. A material of the quantum dots may also be stable composite quantum dots such as a hydrogel loaded quantum dot structure or CdSe—SiO₂. Also, the material of the quantum dots may be perovskite quantum dots. It should be understood that the material of the quantum dots of the present disclosure is not limited to the above materials. In the present disclosure, the nanoparticles are the quantum dots, which is only a description example. However, the nanoparticles of the present disclosure are not limited to the quantum dots.

The surfactant may be a cationic surfactant, an anionic surfactant, a zwitterionic surfactant, or part of a non-ionic surfactant, which are easy to be ionized in a solvent. The cationic surfactant may be an amine salt amine surfactant such as a primary amine salt, a secondary amine salt, or a tertiary amine salt. Also, the cationic surfactant may be a quaternary ammonium salt anionic surfactant. Also, the cationic surfactant may be a heterocyclic cationic surfactant including a nitrogen-containing morpholine ring, a nitrogen-containing pyridine ring, a nitrogen-containing imidazole ring, a nitrogen-containing piperazine ring, or a nitrogen-containing quinoline ring. Also, the cationic surfactant may be rochelle salt cationic surfactant such as a rochelle salt compound, a sulfonium salt compound, an iodine rochelle salt compound, or a rochelle salt compound. Specifically, the cationic surfactant may be a chloride compound or a bromide compound, such as alkyl trimethyl ammonium chloride, alkyl benzyl dimethyl ammonium chloride, dialkyl dimethyl ammonium chloride, trimethyl dodecyl ammonium chloride, cetyl pyridinium chloride, dodecylpyridinium bromide, cetylpyridinium chloride, or cetylpyridinium bromide.

The anionic surfactant includes four categories of carboxylate, sulfonate, sulfate, and phosphate. Carboxylate anionic surfactants include potassium, sodium, ammonium, or triethanolammonium salts having higher fatty acids. For example, alkali metal soaps (monovalent soaps), alkaline earth metal soaps (divalent soaps), organic amine soaps (triethanolamine soaps), naphthates of metals, such as cobalt, aluminum, or iron, or surfactants such as stearate. Sulfonate anionic surfactants include alkyl benzene sulfonate, α-olefin sulfonate, alkyl sulfonate, α-sulfomonocarboxylate, fatty acid sulfoalkyl ester, succinate sulfonate, alkyl naphthalene sulfonate, petroleum sulfonate, lignin sulfonate, or alkyl glyceryl ether sulfonate. For example, organic sulfonate surfactants such as sodium dioctyl succinate sulfonate, calcium dodecyl benzene sulfonate, sodium dodecyl benzene sulfonate, or barium dinonyl naphthalene sulfonate. Sulfate anionic surfactants include two categories fatty alcohol sulfate (primary alkyl sulfate) and secondary alkyl sulfate. Alkyl phosphoric acid ester salts include alkyl phosphoric acid, monoester salts, or diester salts. Also, alkyl phosphoric acid ester salts include phosphoric acid monoester salts of fatty alcohol polyoxyethylene ether, phosphoric acid diester salts of fatty alcohol polyoxyethylene ether, phosphate monoester salts of alkylphenol polyoxyethylene ether, or phosphate diester salts of alkylphenol polyoxyethylene ether.

The zwitterionic surfactant includes a lecithin zwitterionic surfactant, an amino acid zwitterionic surfactant, or a betaine zwitterionic surfactant. An anion of the amino acid zwitterionic surfactant and an anion of the betaine zwitterionic surfactant are mainly carboxylate, and a cation of the carboxylate is a quaternary ammonium salt or an amine salt. Carboxylate having the cation of the quaternary ammonium salt is the amino acid zwitterionic surfactant, and carboxylate having the cation of the amine salt is the betaine zwitterionic surfactant. For example, the amino acid zwitterionic surfactant includes an octadecyl dihydroxyethyl amine oxide, a stearyl amidopropyl amine oxide, or a lauryl amidopropyl amine oxide. The betaine zwitterionic surfactant includes dodecyl ethoxy sultaine, lauryl hydroxypropyl sultaine, dodecyl sultaine, myristyl amidopropyl hydroxypropyl sultaine, or decane hydroxypropyl sultaine.

The non-ionic surfactant may be an N-vinylpyrrolidone polymer (polyvinylpyrrolidone).

Optionally, in some embodiments, preferably, the surfactant is an organic sulfonate surfactant, such as calcium dodecyl benzene sulfonate, sodium dodecyl benzene sulfonate, or barium dinonyl naphthalene sulfonate, which can be strongly bound to quantum dots. Preferably, the surfactant is naphthates of metal such as cobalt, aluminum, or iron. Preferably, the surfactant is a metal soap surfactant such as stearates. Preferably, the surfactant is an organic amine surfactant such as octadecyl dihydroxyethyl amine oxide, an N-vinylpyrrolidone polymer, an organic phosphate surfactant, or a phosphate ester surfactant.

In the present disclosure, the surfactant can be ionized in a solvent and can be bound to a surface of quantum dots. To ensure a binding force between the surface of the quantum dots and the surfactant, optionally, when the surface of the quantum dots is acidic, an alkaline surfactant is used, and when the surface of the quantum dots is a basic group, an acidic surfactant is used. It should be noted that the surface of the quantum dots may only include a surfactant ligand, or may further include other ligands such as an oleic acid ligand, a mercaptans ligand, a carboxylic acid ligand, or an organic amine ligand.

Conventionally, ligands, such as an oleic acid ligand, a mercaptans ligand, a carboxylic acid ligand, or an organic amine ligand, which are difficult to be dissolved in a solvent, are bound to quantum dots, leading to a low quantity of electric charge of quantum dots in a quantum dot solution. When a quantum dot thin film is manufactured by electrodeposition, a driving force required by depositing and forming the quantum dot thin film is overly high because the quantity of electric charge of the quantum dots is overly low. In the present disclosure, the surface of the quantum dots is modified by the surfactant ligand that can be well dissolved in a solvent. Therefore, the surface of the quantum dots is charged. By increasing a degree of ionization of the ligand, the quantity of electric charge of the quantum dots can be increased. Therefore, the required driving voltage when manufacturing the quantum dot thin film by electrodeposition can be reduced.

A method of modifying quantum dots by a surfactant ligand provided by the present disclosure can be applied to a polar solution system and a non-polar solution system, which are respectively described below.

When a solvent is a non-polar solvent, a concentration of the surfactant ligand in a solution is greater than a critical micelle concentration (CMC) to form a reversed micelle that is a colloidal aggregate formed from a surfactant associating from a single ion or a molecule when it exceeds a certain concentration in a solution. The CMC is a concentration when properties of the solution are changed or when the colloidal aggregate is formed. When the surfactant is dissolved in an organic solvent and a concentration of the surfactant is greater than the CMC, a colloidal aggregate formed in the organic solvent is the reversed micelle. Generally, an organic solvent such as n-octane, isooctane, or n-octanol can be an organic phase of a reversed micelle system. In the non-polar solution system, ligands, such as oleic acid, mercaptans, carboxylic acids, and organic amines, commonly used in quantum dots are difficult to be ionized. A surface of quantum dots is modified by a surfactant ligand such as a sodium dodecylbenzene sulfonate surfactant or a phosphate ester surfactant. When a concentration of the surfactant ligand is greater than a critical concentration (CMC), multiple molecules of the surfactant ligand are accumulated to form a reversed micelle. A polar part of the surfactant faces inward to form a polar core. The polar core may contain a small amount of water or other impurities. A tail of the non-polar surfactant points outward to a non-polar solvent, so that the quantum dots with ligands bound on the surface of the quantum dots are dissolved in the non-polar solvent. Surfactants which do not form a reverse micelle can exist in a polar core of a reverse micelle to be ionized in the polar core. A group of the ionized surfactants can interact with a surface of the quantum dots, and can be combined with the surface of the quantum dots, making the quantum dots charged. Moreover, the higher the concentration of the surfactant, the more reversed micelles are formed, the more the surfactant is ionized, the more charged surfactants that can be adsorbed on the surface of the quantum dots, and the greater the quantity of electric charge of the quantum dots. Take a quantum dot shell as CdS and a surfactant ligand as sodium dodecylbenzene sulfonate as an example, multiple sodium dodecylbenzene sulfonates form a reversed micelle that dissolved in a non-polar solvent. Sodium dodecylbenzene sulfonate, which does not form a reverse micelle, is ionized in a polar core of the reversed micelle. Ionization of the surfactant is a dynamic exchange reaction. In the dynamic exchange reaction, a polar ion, such as a cation Nat, ionized at a polar point of the polar core and is captured by the polar core. An ionized non-polar ion, such as a dodecylbenzene sulfonic acid ion that is strongly bound to a surface of the quantum dots, is adsorbed on the surface of the quantum dots. Since dodecylbenzene sulfonic acid is ionized, it is negatively charged, which increases a quantity of electric charge on the surface of the quantum dots.

In a non-polar solvent, to increase a quantity of electric charge on a surface of quantum dots, a mass ratio of a surfactant to the quantum dots can range from 1% to 50%. With increase of a mass fraction of the surfactants, the quantity of electric charge of the quantum dots will also be increased. However, considering that photoelectric properties of the quantum dots may be affected, different quantum dots require different types and different contents of ligands. If an amount of a surfactant ligand is too high, photoelectric properties of quantum dots may be affected. Therefore, a mass ratio of a surfactant to quantum dots should be controlled at 50%. Preferably, the mass ratio of the surfactant to the quantum dots ranges from 20% to 50%.

Experiments have confirmed that when a mass ratio of a surfactant to quantum dots ranges from 1% to 50%, a driving voltage for forming a quantum dot film by electrodeposition can be reduced to 50V to 192V. When the mass ratio of the surfactant to the quantum dots ranges from 20% to 50%, in a non-polar solvent, a driving voltage for forming a quantum dot film by electrodeposition can be reduced to 50V to 150V.

The nanoparticle film of the present application can also be formed in a polar solution system. The polar solvent can be ethanol, water, or propylene glycol methyl ether acetate (PGMEA). Commonly used ligands for quantum dots, such as oleic acid, mercaptans, carboxylic acids, and organic amines, can be ionized in the polar solvent. However, a degree of ionization and an amount of the ligands are low, leading to a low quantity of electric charge of the quantum dots. Surfactants can also be used to modify quantum dots in the polar solution systems. In the polar solvents, the surfactants are directly ionized, and a degree of ionization is much higher than that of conventional quantum dot ligands, leading to a high quantity of electric charge of the quantum dots. The degree of ionization of the surfactant in the polar solution is relatively high compared with that in the non-polar solution system. Therefore, a concentration of the surfactant is not necessary to be too high, and a mass ratio of the surfactant to the quantum dots can range from 1% to 5%. Of course, to further increase a quantity of electric charge, the mass ratio of the surfactant to the quantum dots may also range from 1% to 50%.

Experiments have confirmed that when the mass ratio of the surfactant to quantum dots ranges from 1% to 50%, a driving voltage for forming a quantum dot film by electrodeposition can be reduced to 1V to 48V. When the mass ratio of the surfactant to the quantum dot ranges from 20% to 50%, the driving voltage for forming the quantum dot film by electrodeposition can be reduced to 1V to 10V.

All commercially available quantum dot materials have an initial ligand on their surface to facilitate dispersion in a solvent. Nanoparticles having a surfactant, such as a phosphate ester surfactant, strongly bound to their surface can be formed by performing a ligand exchange reaction between the surfactant and the initial ligand or by directly adding the surfactant into a quantum dot solution to replace the initial ligand. The ligand exchange reaction can completely replace the initial ligand with the surfactant. It should be noted that a complete replacement means that the initial ligand cannot be detected by an instrument. Replacing the initial ligand by directly adding the surfactant into a quantum dot solution has a relatively low replacement ratio, but still can satisfy requirements of the present disclosure. For example, a phosphate ester surfactant and quantum dots, such as CdS/ZnS, can be strongly bound to each other. For example, in core-shell quantum dots, when a material of the shell is CdS/ZnS, an initial ligand is a carboxyl ligand or an amino ligand. An end of the initial ligand is sulfhydryl, and another end of the initial ligand is carboxyl and amino. A surface of the quantum dots and the initial ligand are bound to each other because interaction between an atom S and a sulfhydryl group of the initial ligand. The carboxyl group and the amine group at the end are ionized. However, a binding force between the phosphate ester surfactant and the atom S is stronger than a binding force between the sulfhydryl group and the atom S. The phosphate ester surfactant can deprive a binding position between the S atom of the CdS/ZnS and the initial ligand, thereby replacing the initial ligand on the surface of the quantum dots with the phosphate ester surfactant.

Specifically, a method of providing a nanoparticle solution may include following steps:
providing an initial nanoparticle, wherein a surface of the nanoparticle is provided with an initial ligand;
mixing the initial nanoparticle with a surfactant ligand to perform a ligand exchange reaction, thereby obtaining a nanoparticle with the surfactant ligand on its surface; and
dissolving the nanoparticle with the surfactant ligand on its surface into a solvent, thereby forming the nanoparticle solution.

In a non-polar solvent, to form a reversed micelle to increase a quantity of electric charge of the surface of the nanoparticle, a concentration of the surfactant ligand on the surface of the nanoparticle needs to be high. Therefore, preferable, the ligand exchange reaction is applied to form the nanoparticle with the surfactant ligand on its surface.

Alternatively, the method of providing a nanoparticle solution may include a following step:
providing an initial nanoparticle and a surfactant, dissolving the initial nanoparticle and the surfactant in a solvent, thereby obtaining a nanoparticle with a surfactant on its surface and a nanoparticle solution.

The surface of the initial nanoparticle can be bound to an initial ligand. The initial nanoparticle with the initial ligand on its surface can be obtained by purchase. The surface of the initial nanoparticle can be not bound to an initial ligand. The surface of the initial nanoparticle not bound to the initial ligand can be made in a laboratory. When the surface of the initial nanoparticle does not have the ligand, the surfactant is bound to the surface of the nanoparticle by interacting with atoms on the surface of the initial nanoparticle. When the surface of the initial nanoparticle has the ligand, a binding force between the surfactant and the atoms on the surface of the initial nanoparticle is greater than a binding force between the surface of the initial nanoparticle and the initial ligand. The surfactant replaces the initial ligand and is bound to the surface of the nanoparticle, thereby obtaining the nanoparticle with the surfactant ligand on its surface.

In a polar solvent, a required concentration for binding a surface of nanoparticles to a surfactant is low. Therefore, preferably, the surfactant is directly added into a quantum dot solution to form a nanoparticle with a surfactant ligand on its surface, thereby omitting a ligand exchange reaction to reduce manufacturing cost.

Step 102, forming a nanoparticle film from the nanoparticle solution by electrodeposition.

Specifically, in the step 102, the step of forming the nanoparticle film from the nanoparticle solution by electrodeposition includes following steps:
providing an electrode, and putting the electrode into the nanoparticle solution; and
applying a driving voltage to the electrode to deposit the nanoparticle solution on the electrode to form the nanoparticle film. The driving voltage can be adjusted according to polarity of a solution system and an amount of a ligand. The electrode may be a metal electrode or a transparent oxide electrode such as an indium tin oxide (ITO) electrode.

In the present disclosure, a surfactant ligand is used to modify a surface of a nanoparticle. The surfactant ligand can be ionized in a solvent, thereby increasing a quantity of electric charge of the surface of the nanoparticle and reducing a required driving voltage for electrodepositing a nanoparticle film.

This brings great value to improve a mass production of electrodeposition technologies. Different surfactant ligands and concentrations thereof can be applied to different solvent systems. In a non-polar solvent, the surfactant is used to form a reversed micelle to form a polar point, thereby ionizing a nanoparticle. An end of the ionized surfactant is bound to a surface of the nanoparticle, so that the nanoparticles are charged. The higher the concentration of the surfactant, the more reversed micelles are formed, and the greater the quantity of electric charge of the nanoparticle. In a polar solvent, the surfactant can be directly ionized. Therefore, when quantum dots are in a polar solvent system, a suitable surfactant can be directly added to increase a quantity of electric charge of the quantum dots.

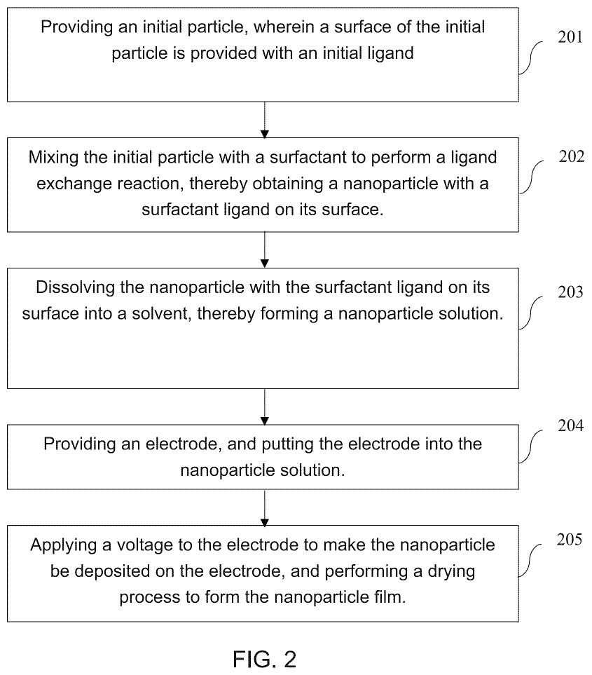

Please refer to FIG. 2, a method of manufacturing a nanoparticle film provided by a first embodiment of the present disclosure includes following steps:
201, providing an initial particle, wherein a surface of the initial particle is provided with an initial ligand.
202, mixing the initial particle with a surfactant to perform a ligand exchange reaction, thereby obtaining a nanoparticle with a surfactant ligand on its surface.
203, dissolving the nanoparticle with the surfactant ligand on its surface into a solvent, thereby forming a nanoparticle solution, wherein a concentration of the surfactant ligand is greater than a critical micelle concentration (CMC) thereof.

In the step 203, the solvent is a non-polar solvent. The surfactant ligand forms a reversed micelle on the surface of the nanoparticle, thereby increasing a quantity of electric charge of the surface of the nanoparticle.

204, providing an electrode, and putting the electrode into the nanoparticle solution.

205, applying a voltage to the electrode to make the nanoparticle be deposited on the electrode, and performing a drying process to form the nanoparticle film. When a mass ratio of the surfactant to a quantum dot ranges from 1% to 50%, a driving voltage ranges from 50V to 192V. Optionally, when the mass ratio of the surfactant to the quantum dot ranges from 20% to 50%, the driving voltage is reduced to 50V to 150V.

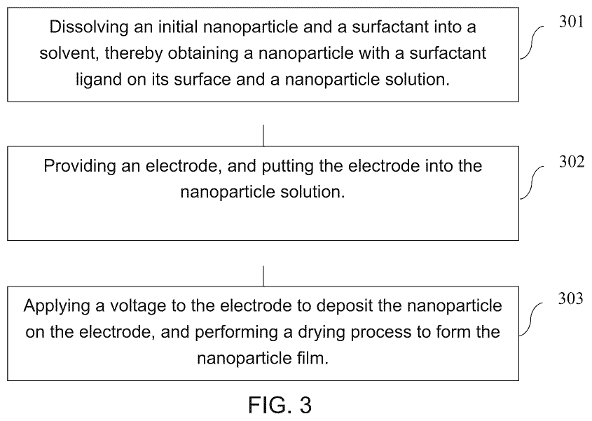

Please refer to FIG. 3, a method of manufacturing a nanoparticle film provided by a second embodiment of the present disclosure is used in a solar solution system. The method includes following steps:

301, dissolving an initial nanoparticle and a surfactant into a solvent, thereby obtaining a nanoparticle with a surfactant ligand on its surface and a nanoparticle solution.

In the step 301, the solvent is a polar solvent.

302, providing an electrode, and putting the electrode into the nanoparticle solution.

303, applying a voltage to the electrode to deposit the nanoparticle on the electrode, and performing a drying process to form the nanoparticle film. When a mass ratio of the surfactant to a quantum dot ranges from 1% to 50%, a driving voltage ranges from 1V to 48V. Optionally, when a mass ratio of the surfactant to the quantum dot ranges from 20% to 50%, the driving voltage can be reduced to 1V to 10V.

The methods of manufacturing the nanoparticle film provided by the present disclosure, which are respectively used in the non-solar solution system and the solar solution system, have been described above. It should be noted that the method of manufacturing the nanoparticle film provided by the first embodiment and the second embodiment can be used in the non-solar solution system and the solar solution system.

Then, a method of manufacturing a nanoparticle film provided by the present disclosure is described in conjunction with specific embodiments.

### First Embodiment

Mixing a core-shell quantum dot (core: CdSe, shell: ZnS) having an initial ligand of oleylamine with isooctyl alcohol polyoxyethylene ether phosphate (phosphate ester surfactant), wherein a mass ratio of the core-shell quantum dot (core: CdSe, shell: ZnS) having the ligand of oleylamine to the isooctyl alcohol polyoxyethylene ether phosphate (phosphate ester surfactant) is 100:1, thereby performing a ligand exchange reaction to form a quantum dot with an isooctyl alcohol polyoxyethylene ether phosphate ligand on its surface. It should be noted that the mass ratio of the core-shell quantum dot (core: CdSe, shell: ZnS) having the ligand of oleylamine does not include a mass of an initial ligand.

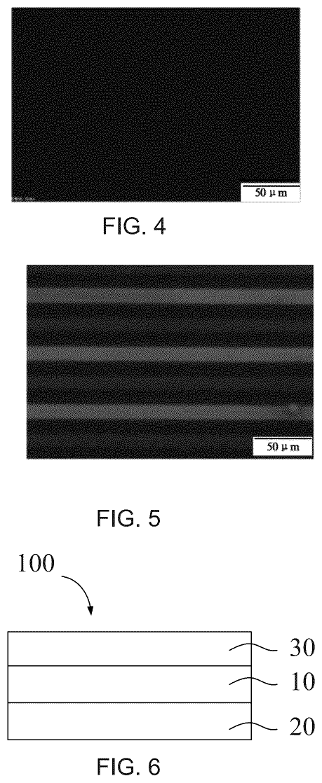

The quantum dot is dissolved into octane. Please refer to FIG. 4, when a voltage is not applied, the quantum dot is distributed in the octane. When a voltage is gradually applied from 0V to a certain degree, please refer to FIG. 5, the quantum dot is deposited on the electrode to form a strip pattern as shown in FIG. 5. Meanwhile, the voltage is a voltage required by electrodeposition, and can be regarded as a quantity of electric charge of the quantum dot.

### Second Embodiment

Mixing a core-shell quantum dot (core: CdSe, shell: ZnS) having an initial ligand of oleylamine with isooctyl alcohol polyoxyethylene ether phosphate (phosphate ester surfactant), wherein a mass ratio of the core-shell quantum dot (core: CdSe, shell: ZnS) having the ligand of oleylamine to the isooctyl alcohol polyoxyethylene ether phosphate (phosphate ester surfactant) is 100:10, thereby performing a ligand exchange reaction to form a quantum dot with an isooctyl alcohol polyoxyethylene ether phosphate ligand on its surface.

The quantum dot is dissolved into octane. When a voltage is gradually applied from 0V to a certain degree, the quantum dot is deposited on the electrode. Meanwhile, the voltage is a driving voltage required by electrodeposition.

### Third Embodiment

Mixing a core-shell quantum dot (core: CdSe, shell: ZnS) having an initial ligand of oleylamine with isooctyl alcohol polyoxyethylene ether phosphate (phosphate ester surfactant), wherein a mass ratio of the core-shell quantum dot (core: CdSe, shell: ZnS) having the ligand of oleylamine to the isooctyl alcohol polyoxyethylene ether phosphate (phosphate ester surfactant) is 100:20, thereby performing a ligand exchange reaction to form a quantum dot with an isooctyl alcohol polyoxyethylene ether phosphate ligand on its surface.

The quantum dot is dissolved into octane. When a voltage is gradually applied from 0V to a certain degree, the quantum dot is deposited on the electrode. Meanwhile, the voltage is a driving voltage required by electrodeposition.

### Fourth Embodiment

Mixing a core-shell quantum dot (core: CdSe, shell: ZnS) having an initial ligand of oleylamine with isooctyl alcohol polyoxyethylene ether phosphate (phosphate ester surfactant), wherein a mass ratio of the core-shell quantum dot (core: CdSe, shell: ZnS) having the ligand of oleylamine to the isooctyl alcohol polyoxyethylene ether phosphate (phosphate ester surfactant) is 100:30, thereby performing a ligand exchange reaction to form a quantum dot with an isooctyl alcohol polyoxyethylene ether phosphate ligand on its surface.

The quantum dot is dissolved into octane. When a voltage is gradually applied from 0V to a certain degree, the quantum dot is deposited on the electrode. Meanwhile, the voltage is a driving voltage required by electrodeposition.

### Fifth Embodiment

Mixing a core-shell quantum dot (core: CdSe, shell: ZnS) having an initial ligand of oleylamine with isooctyl alcohol polyoxyethylene ether phosphate (phosphate ester surfactant), wherein a mass ratio of the core-shell quantum dot (core: CdSe, shell: ZnS) having the ligand of oleylamine to the isooctyl alcohol polyoxyethylene ether phosphate (phosphate ester surfactant) is 100:50, thereby performing a ligand exchange reaction to form a quantum dot with an isooctyl alcohol polyoxyethylene ether phosphate ligand on its surface.

The quantum dot is dissolved into octane. When a voltage is gradually applied from 0V to a certain degree, the quantum dot is deposited on the electrode. Meanwhile, the voltage is a driving voltage required by electrodeposition.

### First Comparison Example

Dissolving a core-shell quantum dot (core: CdSe, shell: ZnS) into octane. When a voltage is gradually applied from 0V to a certain degree, the quantum dot is deposited on the electrode. Meanwhile, the voltage is a driving voltage required by electrodeposition.

TABLE 1
reactants and driving voltages of first to fifth
embodiments and first comparison example

| Experiment | | | driving | |
|---|---|---|---|---|
| number | ligand | solvent | voltage | |
| first | 1 wt % isooctyl alcohol | octane | 192 | V |
| embodiment | polyoxyethylene ether phosphate | | | |
| second | 10 wt % isooctyl alcohol | | 169 | V |
| embodiment | polyoxyethylene ether phosphate | | | |
| third | 20 wt % isooctyl alcohol | | 150 | V |
| embodiment | polyoxyethylene ether phosphate | | | |
| fourth | 30 wt % isooctyl alcohol | | 95 | V |
| embodiment | polyoxyethylene ether phosphate | | | |
| fifth | 50 wt % isooctyl alcohol | | 50 | V |
| embodiment | polyoxyethylene ether phosphate | | | |
| first | oleylamine or oleic acid | | 200 | V |
| comparison | | | | |
| example | | | | |

According to table 1, a driving voltage required by electrodeposition can be reduced by modifying a surface of a quantum dot with a surfactant. In addition, the more surfactant added, the more the driving voltage reduced. When a mass ratio of the surfactant to the quantum dot ranges from 1% to 50%, the driving voltage ranges from 50V to 192V. When the mass ratio of the surfactant to the quantum dot ranges from 20% to 50%, the driving voltage can be reduced to 50V to 150V.

### Sixth Embodiment

Mixing a core-shell quantum dot (core: CdSe, shell: ZnS) having an initial ligand of thiol-PEG-carboxyl (SH-PEG-COOH) with isooctyl alcohol polyoxyethylene ether phosphate in a polar solvent of propylene glycol methyl ether acetate (PGMEA), wherein a mass ratio of the core-shell quantum dot having the ligand of SH-PEG-COOH to the isooctyl alcohol polyoxyethylene ether phosphate is 100:1, thereby forming a quantum dot with an isooctyl alcohol polyoxyethylene ether phosphate ligand on its surface.

Putting an electrode into a quantum dot solution. When a voltage is gradually applied from 0V to a certain degree, the quantum dot is deposited on the electrode. Meanwhile, the voltage is a driving voltage required by electrodeposition.

### Seventh Embodiment

Mixing a core-shell quantum dot (core: CdSe, shell: ZnS) having an initial ligand of SH-PEG-COOH with isooctyl alcohol polyoxyethylene ether phosphate in a polar solvent of PGMEA, wherein a mass ratio of the core-shell quantum dot having the ligand of SH-PEG-COOH to the isooctyl alcohol polyoxyethylene ether phosphate is 100:10, thereby forming a quantum dot with an isooctyl alcohol polyoxyethylene ether phosphate ligand on its surface.

Putting an electrode into a quantum dot solution. When a voltage is gradually applied from 0V to a certain degree, the quantum dot is deposited on the electrode. Meanwhile, the voltage is a driving voltage required by electrodeposition.

### Eighth Embodiment

Mixing a core-shell quantum dot (core: CdSe, shell: ZnS) having an initial ligand of SH-PEG-COOH with isooctyl alcohol polyoxyethylene ether phosphate in a polar solvent of PGMEA, wherein a mass ratio of the core-shell quantum dot having the ligand of SH-PEG-COOH to the isooctyl alcohol polyoxyethylene ether phosphate is 100:20, thereby forming a quantum dot with an isooctyl alcohol polyoxyethylene ether phosphate ligand on its surface.

Putting an electrode into a quantum dot solution. When a voltage is gradually applied from 0V to a certain degree, the quantum dot is deposited on the electrode. Meanwhile, the voltage is a driving voltage required by electrodeposition.

### Ninth Embodiment

Mixing a core-shell quantum dot (core: CdSe, shell: ZnS) having an initial ligand of SH-PEG-COOH with isooctyl alcohol polyoxyethylene ether phosphate in a polar solvent of PGMEA, wherein a mass ratio of the core-shell quantum dot having the ligand of SH-PEG-COOH to the isooctyl alcohol polyoxyethylene ether phosphate is 100:30, thereby forming a quantum dot with an isooctyl alcohol polyoxyethylene ether phosphate ligand on its surface.

Putting an electrode into a quantum dot solution. When a voltage is gradually applied from 0V to a certain degree, the quantum dot is deposited on the electrode. Meanwhile, the voltage is a driving voltage required by electrodeposition.

### Tenth Embodiment

Mixing a core-shell quantum dot (core: CdSe, shell: ZnS) having an initial ligand of SH-PEG-COOH with isooctyl alcohol polyoxyethylene ether phosphate in a polar solvent of PGMEA, wherein a mass ratio of the core-shell quantum dot having the ligand of SH-PEG-COOH to the isooctyl alcohol polyoxyethylene ether phosphate is 100:50, thereby forming a quantum dot with an isooctyl alcohol polyoxyethylene ether phosphate ligand on its surface.

Putting an electrode into a quantum dot solution. When a voltage is gradually applied from 0V to a certain degree, the quantum dot is deposited on the electrode. Meanwhile, the voltage is a driving voltage required by electrodeposition.

### Second Comparison Example

Mixing a core-shell quantum dot (core: CdSe, shell: ZnS) having an initial ligand of SH-PEG-COOH with a polar solvent of PGMEA to form a quantum dot solution.

Putting an electrode into the quantum dot solution. When a voltage is gradually applied from 0V to a certain degree, a quantum dot is deposited on the electrode. Meanwhile, the voltage is a driving voltage required by electrodeposition.

TABLE 2
reactants and driving voltages of sixth to tenth
embodiments and second comparison example

| Experiment | | | driving | |
|---|---|---|---|---|
| number | ligand | solvent | voltage | |
| sixth | 1 wt % isooctyl alcohol | PGMEA | 48 | V |
| embodiment | polyoxyethylene ether phosphate | | | |
| seventh | 10 wt % isooctyl alcohol | | 25 | V |
| embodiment | polyoxyethylene ether phosphate | | | |
| eighth | 20 wt % isooctyl alcohol | | 10 | V |
| embodiment | polyoxyethylene ether phosphate | | | |
| ninth | 30 wt % isooctyl alcohol | | 7 | V |
| embodiment | polyoxyethylene ether phosphate | | | |
| tenth | 50 wt % isooctyl alcohol | | 1 | V |
| embodiment | polyoxyethylene ether phosphate | | | |
| second | oleylamine or oleic acid | | 50 | V |
| comparison | | | | |
| example | | | | |

According to table 2, a driving voltage required by electrodeposition can be reduced by modifying a surface of a quantum dot with a surfactant. In addition, the more surfactant added, the more the driving voltage reduced. When a mass ratio of the surfactant to the quantum dot ranges from 1% to 50%, the driving voltage ranges from 1V to 48V. When the mass ratio of the surfactant to the quantum dot ranges from 20% to 50%, the driving voltage can be reduced to 1V to 10V.

The present disclosure further provides a nanoparticle film which can be used in quantum-dot display fields such as quantum dot color filters (QDCFs), quantum dot light guide plates (QDLGPs), quantum dot light-emitting diodes (QLEDs), and quantum dot organic light-emitting diodes (QD-OLEDs). Also, nanoparticle film can be used in other fields involving other types of nanoparticle patterning processes, such as solar cells and spectrometers.

The nanoparticle film can be manufactured according to the method of manufacturing the nanoparticle film provided by the present disclosure. The nanoparticle film includes a plurality of nanoparticles. The nanoparticles for manufacturing the nanoparticle film may be non-metallic inorganic nanoparticles, metal nanoparticles, colloidal nanosheets, or colloidal nanorods. Optionally, the nanoparticles may be quantum dots. A material of the quantum dots of the present disclosure may be core-shell quantum dots. A luminescent core of the core-shell quantum dots may be one of ZnCdSe₂, InP, Cd₂Sse, CdSe, Cd₂SeTe, or InAs. An inorganic protective shell may be at least one of CdS, ZnSe, ZnCdS₂, ZnS, or ZnO. A material of the quantum dots may also be stable composite quantum dots such as a hydrogel loaded quantum dot structure or CdSe—SiO₂. Also, the material of the quantum dots may be perovskite quantum dots. It should be understood that the material of the quantum dots of the present disclosure is not limited to the above materials.

The surfactant may be a cationic surfactant or an anionic surfactant, which are easy to be ionized in a solvent. The surfactant may be an organic sulfonate surfactant such as calcium dodecyl benzene sulfonate, sodium dodecyl benzene sulfonate, or barium dinonyl naphthalene sulfonate. The surfactant may be naphthates of metal such as cobalt, aluminum, or iron. The surfactant may be a metal soap surfactant such as stearates. The surfactant may be an organic amine surfactant such as an N-vinylpyrrolidone polymer. The surfactant may be at least one of an organic phosphate surfactant or a phosphate ester surfactant. The surfactant of the present disclosure can be ionized and can be bound to a surface of a quantum dot. A binding force between the quantum dot and the surfactant needs to be ensured. Optionally, when the surface of the quantum dot is an acid group, an alkaline surfactant is used. When the surface of the quantum dot is an alkaline group, an acid surfactant is used.

It should be noted that the surface of the quantum dot may only include a surfactant ligand, or may further include other ligands such as an oleic acid, mercaptan, a carboxylic acid, or an organic amine.

Optionally, a mass ratio of the surfactant ligand to the nanoparticle ranges from 1% to 50%. Alternatively, the mass ratio of the surfactant ligand to the nanoparticle ranges from 1% to 5%.

The nanoparticle film provided by the present disclosure can be formed by electrodeposition with a relatively low driving voltage.

The present disclosure further provides a display panel, including the above nanoparticle film that is a quantum dot film.

Please refer to FIG. 6. The display panel of the first embodiment of a QLED display panel. A quantum dot film 10 is a luminescent layer of a QLED. Specifically, a display panel 100 includes a first electrode 20, a second electrode 30, and a quantum dot film 10 disposed between the first electrode 20 and the second electrode 30. It should be understood that the display panel 100 may further include a hole transport layer, a hole injection layer, an electron transport layer, and an electron injection layer.

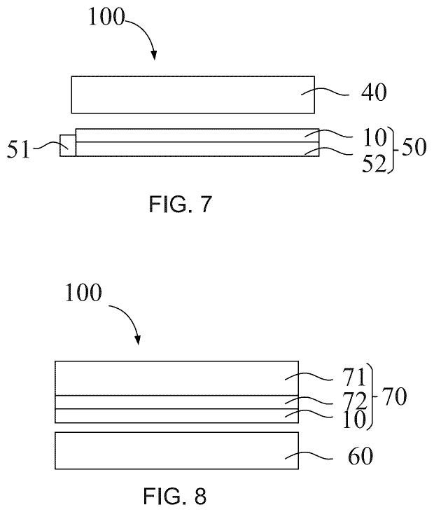

Please refer to FIG. 7, the second embodiment of the present disclosure provides a liquid crystal display (LCD) panel. A quantum dot 10 is a color conversion layer of a backlight module of an LCD. Specifically, a display panel 100 includes a liquid crystal cell 40 and a backlight module 50 disposed on a non-luminescent side of the liquid crystal cell 40. The backlight module 50 includes a light source 51, a light guide plate 52, and the quantum dot film 10. The light source 51 is disposed on a lateral surface of the light guide plate 52. The light source 51 may be a blue light source or a white light source. The quantum dot film 10 is disposed between the light guide plate 52 and the liquid crystal cell 40. The quantum dot film 10 is used to convert a color of light, which is emitted from the light source 51 to the light guide plate 52 and is emitted from the light guide plate 52, into a required color such as green or red.

Please refer to FIG. 8, the third embodiment of the present disclosure provides an LED display panel. A quantum dot 10 is a color conversion layer of a backlight module of an LED. Specifically, a display panel 100 includes a light-emitting substrate 60 and a color conversion substrate 70 disposed opposite to each other. The light-emitting substrate 60 is provided with a plurality of luminescent components (not shown) arranged in an array manner. The luminescent components may be mini-LEDs or micro LEDs. The color conversion substrate 70 includes a substrate 71, a color filter layer 72 disposed on a side of the substrate 71 facing the light-emitting substrate 60, and a quantum dot film 10 disposed on a side of the color filter layer 72 facing the light-emitting substrate 60. The color filter layer 72 and the quantum dot film 10 may also be collectively referred to as a QDCF film.

In the display panel provided by the present disclosure, the nanoparticle film is used. The surface of the nanoparticle film is provided with a surfactant ligand. Therefore, the nanoparticle film can be manufactured by electrodeposition with a relatively low driving voltage.

Detailed descriptions of embodiments of the present disclosure are provided above. Principles and embodiments of the present disclosure are illustrated with reference to specific examples. The descriptions of the above embodiment are merely used to help those skilled in the art understand the present disclosure. Furthermore, for those skilled in the art, specific embodiments and applications may be modified according to the spirit of the present disclosure. In summary, the contents of the specification shall not be construed as causing limitations to the present disclosure.

1. A method of manufacturing a nanoparticle film, comprising following steps:
providing a nanoparticle solution, wherein the nanoparticle solution comprises a solvent and a plurality of nanoparticles distributed in the solvent, and a surface of the nanoparticles is provided with a surfactant ligand; and
forming the nanoparticle film from the nanoparticle solution by electrodeposition.

2. The method of claim 1, wherein the solvent is a non-polar solvent, and a concentration of the surfactant ligand is greater than a concentration of a critical micelle concentration.

3. The method of claim 2, wherein a mass ratio of the surfactant ligand to the nanoparticles ranges from 1% to 50%.

4. The method of claim 2, wherein the step of forming the nanoparticle film from the nanoparticle solution by electrodeposition comprises following steps:
providing an electrode, and putting the electrode into the nanoparticle solution; and
applying a driving voltage to the electrode to make the nanoparticle solution be deposited on the electrode to form the nanoparticle film, wherein the driving voltage ranges from 50V to 150V.

5. The method of claim 1, wherein the solvent is a polar solvent, and a mass ratio of the surfactant ligand to the nanoparticles ranges from 1% to 50%.

6. The method of claim 5, wherein the mass ratio of the surfactant ligand to the nanoparticles ranges from 1% to 5%.

7. The method of claim 5, wherein the step of forming the nanoparticle film from the nanoparticle solution by electrodeposition comprises following steps:
providing an electrode, and putting the electrode into the nanoparticle solution; and
applying a driving voltage to the electrode to make the nanoparticle solution be deposited on the electrode to form the nanoparticle film, wherein the driving voltage ranges from 1V to 10V.

8. The method of claim 1, wherein the step of providing the nanoparticle solution comprises following steps:
providing a plurality of initial nanoparticles, wherein a surface of the initial nanoparticles is provided with an initial ligand;
mixing the initial nanoparticles with a surfactant to obtain the nanoparticles having the surfactant ligand on the surface of the nanoparticles, wherein a ligand exchange reaction occurs between the initial nanoparticles and the surfactant; and
dissolving the nanoparticles having the surfactant ligand on the surface of the nanoparticles into the solvent to form the nanoparticle solution.

9. The method of claim 1, wherein the step of providing the nanoparticle solution comprises a following step:
dissolving a plurality of initial nanoparticles and the surfactant into the solvent to obtain the nanoparticles having the surfactant ligand on the surface of the nanoparticles and form the nanoparticle solution.

10. The method of claim 1, wherein the nanoparticles are a plurality of quantum dots.

11. The method of claim 11, wherein the surfactant ligand is selected from at least one of an organic sulfonate surfactant ligand, a metal soap sulfonate surfactant ligand, an organic amine surfactant ligand, an N-vinylpyrrolidone polymer, an organic phosphate surfactant ligand, or a phosphate ester surfactant ligand.

12. A nanoparticle film, comprising a plurality of nanoparticles, wherein a surface of the nanoparticles is provided with a surfactant ligand.

13. The nanoparticle film of claim 12, wherein a mass ratio of the surfactant ligand to the nanoparticles ranges from 1% to 50%.

14. The nanoparticle film of claim 12, wherein a mass ratio of the surfactant ligand to the nanoparticles ranges from 1% to 5%.

15. The nanoparticle film of claim 12, wherein the nanoparticles are a plurality of quantum dots.

16. The nanoparticle film of claim 12, wherein the surfactant ligand is selected from at least one of an organic sulfonate surfactant ligand, a metal soap sulfonate surfactant ligand, an organic amine surfactant ligand, an N-vinylpyrrolidone polymer, an organic phosphate surfactant ligand, or a phosphate ester surfactant ligand.

17. A display panel, comprising the nanoparticle film of claim 12, wherein the nanoparticles are a plurality of quantum dots.

18. The display panel of claim 17, wherein a mass ratio of the surfactant ligand to the nanoparticles ranges from 1% to 50%.

19. The display panel of claim 17, wherein a mass ratio of the surfactant ligand to the nanoparticles ranges from 1% to 5%.

20. (canceled)
